(19) United States
(12) Patent Application Publication
(10) Pub. No.: US 2010/0173135 A1
(43) Pub. Date: Jul. 8, 2010

(54) Method of Controlling Surface Roughness of a Flexographic Printing Plate

(76) Inventors: Jonghan Choi, Smyrna, GA (US); Kerry O'Brate, Decatur, GA (US)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/348,981

(22) Filed: Jan. 6, 2009

(51) Int. Cl. B32B 3/00; G03F 7/20

(52) U.S. Cl. 428/195.1; 430/306

(57) ABSTRACT

A method of controlling surface roughness of a flexographic printing element during thermal processing. The printing blank comprises at least one photocurable layer on a support layer, the at least one photocurable layer comprising: (1) a binder comprising styrene-butadiene-styrene; (2) at least one fast curing monomer; (3) at least one slow curing monomer; and (4) a photoinitiator. The printing blank is selectively imagewise exposing the printing plate blank to actinic radiation from the top of the printing element blank to selectively crosslink and cure portions of the at least one photocurable layer and then thermally processed to remove uncured portions of the at least one photocurable layer, thereby revealing the relief image in the at least one photocurable layer. Surface roughness of the relief image printing element after thermal processing is controlled to less than about 1,000 nm.

### FIELD OF THE INVENTION

The present invention relates to a method of tailoring surface roughness of flexographic printing elements upon thermal processing.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography. Flexographic printing plates are relief plates with image elements raised above open areas. Such plates offer a number of advantages to the printer, based chiefly on their durability and the ease with which they can be made.

A typical flexographic printing plate as delivered by its manufacturer, is a multilayered article made of, in order, a backing or support layer, one or more unexposed photocurable layers, a protective layer or slip film, and a cover sheet. A typical continuous-in-the-round (CITR) photopolymer sleeve generally comprises a sleeve carrier (support layer) and at least one unexposed photocurable layer on top of the support layer.

It is highly desirable in the flexographic prepress printing industry to eliminate the need for chemical processing of printing elements in developing relief images, in order to go from plate to press more quickly. Processes have been developed whereby photopolymer printing plates are prepared using heat and the differential melting temperature between cured and uncured photopolymer is used to develop the latent image. The basic parameters of this process are known, as described in U.S. Pat. Nos. 5,279,697, 5,175,072 and 3,264,103, in published U.S. patent publication Nos. US 2003/0180655, and U.S. 2003/0211423, and in WO 01/88615, WO 01/18604, and EP 1239329, the teachings of each of which are incorporated herein by reference in their entirety. These processes allow for the elimination of development solvents and the lengthy plate drying times needed to remove the solvent. The speed and efficiency of the process allow for use of the process in the manufacture of flexographic plates for printing newspapers and other publications where quick turnaround times and high productivity are important.

The photopolymer layer allows for the creation of the desired image and provides a printing surface. The photopolymers used generally contain binders, monomers, photoinitiators, and other performance additives. Examples of suitable photopolymer compositions include those described in U.S. Patent Application Publication No. 2004/0146806 to Roberts et al., the teachings of which are incorporated herein by reference in their entirety. Various photopolymers such as those based on polystyrene-isoprene-styrene, polystyrene-butadiene-styrene, polyurethanes and/or thiolenes as binders are useful. Preferred binders include polystyrene-isoprene-styrene (SIS), and polystyrene-butadiene-styrene (SBS), especially block co-polymers of the foregoing.

The composition of the photopolymer should be such that there exists a substantial difference in the melt temperature between the cured and uncured polymer. It is precisely this difference that allows the creation of an image in the photopolymer when heated. The uncured photopolymer (i.e., the portions of the photopolymer not contacted with actinic radiation) will melt or substantially soften while the cured photopolymer will remain solid and intact at the temperature chosen. Thus the difference in melt temperature allows the uncured photopolymer to be selectively removed thereby creating an image.

The printing element is then selectively exposed to actinic radiation, which is traditionally accomplished in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer, which is also sensitive to laser ablation. A laser is then used to ablate selected areas of the actinic radiation opaque layer creating an in situ negative, and the printing element is then flood exposed through the in situ negative. In the third alternative, a focused beam of actinic radiation is used to selectively expose the photopolymer. Any of these alternative methods produces an acceptable result, with the criteria being the ability to selectively expose the photopolymer to actinic radiation thereby selectively curing portions of the photopolymer.

Once the photopolymer layer of the printing element has been selectively exposed to actinic radiation, it can then be developed using heat. In a typical thermal development process, the photopolymer layer is softened by passing the printing element over a heated roller, the roller typically being heated to a temperature of at least about 70° C. The exact temperature depends upon the properties of the particular photopolymer being used. However, two primary factors are typically considered in determining the development temperature:
1. The temperature of the heated roller is preferably set between the melt temperature of the uncured photopolymer on the low end and the melt temperature of the cured photopolymer on the upper end. This will allow selective removal of the photopolymer, thereby creating the image.
2. The higher the temperature of the heated roller, the quicker the process time will be. However, the temperature of the heated roller should not be so high as to exceed the melt temperature of the cured photopolymer or so high that it will degrade the cured photopolymer. The temperature should be sufficient to melt or substantially soften the uncured photopolymer thereby allowing it to be removed.

Once the printing element has been heated, uncured photopolymer can be melted or removed, thus revealing the relief image. In a preferred embodiment, the heated printing element is contacted with a material that will absorb or otherwise remove the softened or melted uncured photopolymer. This removal process is generally referred to as “blotting,” which is typically accomplished using a screen mesh or an absorbent fabric. Either woven or non-woven fabric can be used and the fabric may be polymer-based or paper, so long as the fabric can withstand the operating temperatures involved. In most instances, blotting is accomplished by using rollers to bring the material and the heated printing plate element into contact.

U.S. Pat. No. 5,175,072 to Martens, the subject matter of which is herein incorporated by reference in its entirety, describes the removal of uncured portions of the photopolymer by using an absorbent sheet material. The uncured photopolymer layer is heated by conduction, convection, or other heating method to a temperature sufficient to effect melting. By maintaining more or less intimate contact of the absorbent sheet material with the photocurable layer, a transfer of the uncured photopolymer from the photopolymer layer to the absorbent sheet material takes place. While still in the heated condition, the absorbent sheet material is separated from the cured photopolymer layer in contact with the support layer to reveal the relief structure. After cooling, the resulting flexographic printing plate can be mounted on a printing plate cylinder.

Upon completion of the blotting process, the printing plate element is preferably post-exposed to further actinic radiation in the same machine, cooled and is then ready for use.

Depending upon the particular application, the printing element may also comprise other optional components. For instance, it is frequently preferable to use a removable coversheet over the photopolymer layer to protect the layer during handling. If used, the coversheet is removed either just before or just after the selective exposure to actinic radiation. Other layers, such as slip layer or masking layers, as described for example in U.S. Pat. No. 5,925,500 to Yang et al., the teachings of which are incorporated herein by reference in their entirety, may also be used.

One problem with current blotting methods is that thermally developed printing plates may be vulnerable to high surface roughness (SR) due to the blotting materials used to remove uncured photopolymer. As used herein surface roughness is determined using ASTM standard ASME B46.1 and is reported as average roughness, Ra. In addition to removing uncured photopolymers, these blotting materials may embed patterns of the blotting material in the cured photopolymer relief. In other words, if the surface roughness of the blotter is excessive, it may print blotter patterns, especially on the solid areas, leading to inconsistent ink coverage and low solid ink density (SID). If the surface roughness is moderately rough (i.e., ˜500-700 nm), it may enhance the ink transfer due to an increased surface area. However, if the surface is excessively rough (e.g., >1000 nm), the solid areas may contain blotter patterns and thus cause low SID on the printed solid areas. Therefore, it is important to have the capability to tailor the magnitude of the SR to optimize print quality.

There are three different types of flexographic printing plate blanks that are commonly used for producing relief image printing plates: (1) uncapped analog plates (i.e., producing using a negative); (2) digital plates (i.e., computer-generated in Situ negative) processed in solvent; and (3) digital plates processed by thermal development. The surface roughness of the uncapped analog plate and the digital plate processed in solvent is typically much lower (surface roughness of ˜80-150 nm) than that of the digital plate thermally processed (surface roughness of ˜400-800+ nm). These results are generally the result of a given processing method employed. The inventors of the present invention have determined that if the surface roughness of the printing element is higher than about 1,000 nm, there is a chance that blotter patterns embedded in the printing relief as a result of thermal processing may print and have a negative impact optical density. Therefore, it would be desirable to tailor the surface roughness of the printing element upon thermal processing to a desired level.

Currently, all thermally developable printing plates available on the market are believed to be styrene-isoprene-styrene (SIS)-rubber-based plates. As such, they tend to be less susceptible to the formation of blotter patterns during thermal development. On the other hand, styrene-butadiene-styrene (SBS)-rubber-based plates tend to be more vulnerable to the formation of blotter patterns but also have unique physical properties that make them desirable for use in producing relief image printing elements. Therefore, it is an object of the present invention to engineer photopolymer resin formulations for use in producing thermally processed relief image printing plates that have a lower the SR in order to take advantage of SBS-rubber's unique physical properties such as high ozone resistance and low tackiness.

### SUMMARY OF THE INVENTION

It is an object of the present invention to utilize SBS-rubber-based plate formulations that are substantially unaffected by potential blotter patterns upon thermal processing.

It is another object of the present invention to tailor the surface roughness of relief image printing plates upon thermal development through the use of a particular blend of monomers.

It is still another object of the present invention to tailor the surface roughness of relief image printing plates upon thermal development by optimizing various process parameters of the thermal development process.

To that end, the present invention relates generally to a method of controlling surface roughness of a flexographic printing element during thermal processing, the method comprising the steps of:
a) providing a printing element blank, said printing element blank comprising:
   i) a support layer;
   ii) at least one photocurable layer on the support layer, the at least one photocurable layer comprising:
      1) a binder comprising styrene-butadiene-styrene;
      2) at least one fast curing monomer;
      3) at least one slow curing monomer; and
      4) a photoinitiator;
   iii) optionally, an actinic radiation opaque laser ablatable layer on top of the at least one photocurable layer, said laser ablatable layer being capable of being ablated by exposure to infrared laser radiation; and
   iv) optionally, a removable coversheet;
b) selectively imagewise exposing the printing plate blank to actinic radiation to selectively crosslink and cure portions of the at least one photocurable layer; and
c) thermally processing the at least one photocurable layer to remove uncured portions of the at least one photocurable layer, thereby revealing the relief image in the at least one photocurable layer;

wherein surface roughness of the relief image printing element after thermal processing is less than about 1,000 nm.

### BRIEF DESCRIPTION OF THE DRAWINGS

For a filler understanding of the invention, reference is had to the following description taken in connection with the accompanying figures, in which:

FIG. 1 depicts the content of hexanediol diacrylate (HDDA) in various photopolymer compositions.

FIG. 2 depicts a statistical analysis of the effect of HDDA on surface roughness, where the surface roughness values are transformed into inverse square root and the actual surface roughness values are denoted by the horizontal lines.

FIG. 3 depicts SEM pictures of two types of blotting materials.

Also, while not all elements may be labeled in each figure, all elements with the same reference number indicate similar or identical parts.

### DETAILED DESCRIPTION OF THE PREFERRED EMBODIMENTS

When it comes to surface roughness of thermally processed plates, the following factors are generally considered to be important: (1) squeeze types; (2) hot roll temperature; (3) IR laser power; (4) forward exposure times, (5) blotter types; and (6) type of photoresin. In order to identify which of these factors were the most critical to surface roughness, a screening test was run, and it was determined that the most significant factors influencing surface roughness in the thermal development step include (1) hot roll temperature; (2) front exposure time; (3) blotter type; and (4) the type of photoresin used. Generally, it was found that as the hot roll temperature and front exposure time increases, surface roughness decreases. Furthermore, the most significant factors for relief include (1) hot roll temperature and (2) blotter type. In particular, as the temperature of the hot roller increases, relief increases.

Surface roughness induced by thermal processing is dependent on the type of photoresin. In addition, increased hot roll temperature and front exposure time function to reduce surface roughness of the plates when thermally processed.

Generally, the inventors of the present invention have determined that it is preferable to come up with photoresin formulations that give low surface roughness upon thermal processing. In addition, if it is not possible to modify the photoresin composition, then surface roughness can be tailored by elevating the hot roll temperature and increasing the front exposure time to specified levels where no adverse effect is imparted such as dimensional stability (i.e., shrinkage and/or deformation) and dot stability.

In one embodiment, the present invention relates generally to a method of controlling surface roughness of a flexographic printing element during thermal processing, the method comprising the steps of:
a) providing a printing element blank, said printing element blank comprising:
   i) a support layer;
   ii) at least one photocurable layer on the support layer, the at least one photocurable layer comprising:
      1) a binder comprising styrene-butadiene-styrene;
      2) at least one fast curing monomer;
      3) at least one slow curing monomer; and
      4) a photoinitiator; iii) optionally, an actinic radiation opaque laser ablatable layer on top of the at least one photocurable layer, said laser ablatable layer being capable of being ablated by exposure to infrared laser radiation; and
   iv) optionally, a removable coversheet;
b) selectively imagewise exposing the printing plate blank to actinic radiation to selectively crosslink and cure portions of the at least one photocurable layer; and
c) thermally processing the at least one photocurable layer to remove uncured portions of the at least one photocurable layer, thereby revealing the relief image in the at least one photocurable layer.

The present invention relates to the tailoring of the surface roughness of flexographic printing elements. In a preferred embodiment, it is preferred that the surface roughness is less than about 1,000 nm upon thermal processing and preferably, the surface roughness of the relief image printing plate after thermal processing is controlled to less than about 500 nm. In addition, it is also desirable to have high ink transfer to increase optical density upon printing. While slight surface roughness is conducive to increasing the optical density, if the surface roughness is too excessive, the optical density is decreased due to failure to make intimate contact between the printing plate surface and a given substrate.

The thermal processing step typically comprises heating the at least one layer of photocurable material to soften uncured portions of the at least one photocurable layer and causing contact between the at least one photocurable layer and a blotting material, wherein the blotting material removes the softened uncured portions of the at least one photocurable layer. The thermal processing step is typically performed at a temperature of between about 140 and about 180° C., more preferably at a temperature of between about 170 and 180° C.

The inventors of the present invention have determined that surface roughness can be tailored in the printing plate in various ways.

Firstly, surface roughness can be tailored by employing various concentrations of particular unsaturated acrylic monomers. In one embodiment, the unsaturated acrylic monomer is hexanediol diacrylate (HDDA). However, any type of unsaturated acrylic monomer that has fast curing (or imaging) speed can be used, such as for example trimethylolpropane triacrylate (TMPTA), butanediol diacrylate, butylene glycol diacrylate, ethylene glycol diacrylate, pentanediol diacrylate, diethylene glycol diacrylate, propanediol diacrylate, tripropylene glycol diacrylate, diethylene glycol diacrylate, glycerol triacrylate, pentaerylthritol triacrylate, trimethylpropane triacrylate, propyloxyethylated trimethylolpropane triacrylate, petaerythritol tetraacrylate, and other similar monomers. The unsaturated acrylic monomer is typically present in the composition at a concentration of about 1-20% by weight, based on the total weight of the composition.

Other monomers that may also be included in the composition include hexanediol dinethacrylate (DMA) and trimethylolpropane trimethacrylate (TMPTMA), ethylene glycol dimethacrylate, butylene glycol dimethacrylate, propanediol dimethacrylate, butylenes glycol dimethacrylate, propanediol dimethacrylate, pentanediol dimethacrylate, pentaerythritol trimetharcylate, butanetriol trimethacrylate, pentaerythritol tetramethacrylate, and trimethylol propane trimethacrylate. However, these unsaturated methacrylic monomers tend to give slow image speed and thus tend to increase the surface roughness. The difference in image speed between unsaturated acrylic monomers and unsaturated methacrylic monomers can be readily demonstrated by determining the minimum holding time (MHT) required to hold a given dot size and line screen (eg. 2%-150 lpi) resulting in an inverse measure of image speed. In general acrylic monomers are faster curing than methacrylic monomers.

It is generally desirable to use a combination of a fast curing unsaturated acrylic monomer and a slow curing unsaturated methacrylic monomer in order to tailor the surface roughness of the finished relief image printing plate. In one embodiment, the printing plate formulations of the instant invention typically include at least two monomers, i.e., at least HDDA (or TMPTA) and either HDDMA and/or TMPTMA. HDDA is the fast monomer and HDDMA or TMPTMA is the slow monomer. When HDDA is used as the major monomer (about 5% by weight or higher), the surface roughness of the finished plate formulation is generally low enough (i.e., 500 nm).

Binders, which are usable in the composition, include styrene-isoprene-styrene or styrene-butadiene-styrene block copolymers. For various reasons, discussed above, styrene-butadiene-styrene block copolymers are particularly preferred. In addition, the composition may also include various photopolymers, plasticizers and antioxidants as is generally well known in the art and as described for example in U.S. Pat. No. 6,773,859 to Fan et al., U.S. Pat. No. 6,558,876 to Fan and U.S. Patent Publication Nos. 2005/0123856 and 2005/023899, both to Roberts, the subject matter of which is herein incorporated by reference in its entirety. The composition may also comprise various UV absorbents, dyes, etc. as would be well known to those skilled in the art.

Table 1 describes monomer levels of various photopolymer formulations that are usable in the practice of the invention.

TABLE 1
Monomer levels of various photopolymer formulations

| | HDDA Content | HDDMA Content | TMPTMA Content |
|---|---|---|---|
| Example | % by weight | % by weight | % by weight |
| 1 | 0.99 | 7.36 | — |
| 2 | 5.62 | — | 2.25 |
| 3 | 0.99 | 6.36 | 1.00 |
| 4 | 7.36 | 0.99 | — |
| 5 | 5.36 | — | 2.13 |
| 6 | 6.86 | 0.99 | — |
| 7 | 1.23 | 9.12 | — |
| 8 | 6.59 | 2.26 | — |

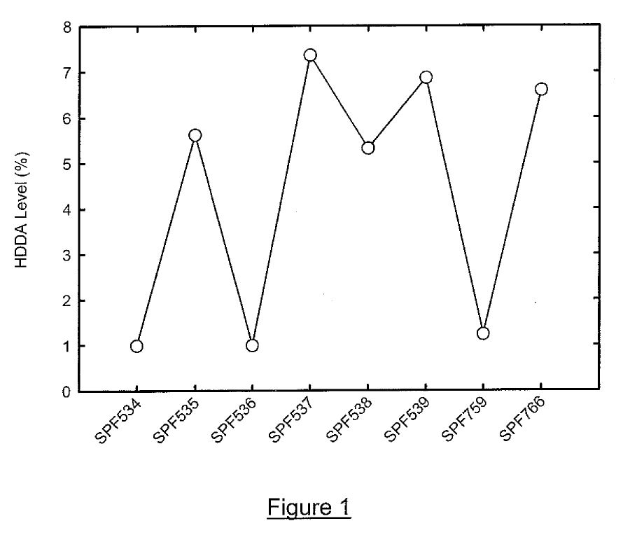

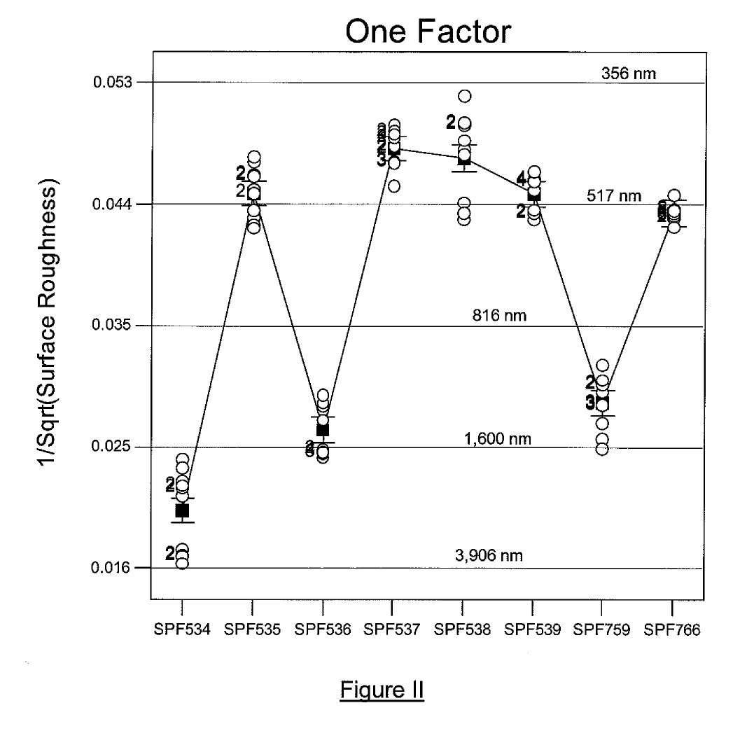

FIG. 1 depicts the HDDA contents of various photopolymer concentrations. FIG. 2 depicts a statistical analysis of the effect of HDDA content on surface roughness. The actual surface roughness values are denoted by the horizontal lines. As can be seen from this statistical analysis, the photopolymer formulations with higher amounts of fast curing monomer (HDDA) typically had the lowest surface roughness.

The imagewise exposure step is performed for between about 5 and about 15 minutes, more preferably for between about 8 and about 10 minutes (at a bulb intensity of ˜15 mW/cm²).

The present invention also relates to a thermally processed relief image printing element, wherein the relief image printing element comprises at least one layer of photocurable material that crosslinks and cures upon exposure to actinic radiation, the at least one layer of photocurable material comprising (a) a binder comprising a styrene-butadiene-styrene block copolymer, (b) a fast curing monomer, and (c) a slow monomer; wherein after thermal processing, the relief image printing element has a surface roughness of less than about 1,000 μm, more preferably, less than about 500 nm.

A flexographic printing element is produced from a photocurable printing blank by imaging the photocurable printing blank to produce a relief image on the surface of the printing element. This is generally accomplished by selectively exposing the photocurable material to actinic radiation, which exposure acts to harden or crosslink the photocurable material in the irradiated areas. SIS-based plates tend to be less susceptible to bearing blotter patterns upon thermal processing. For this reason, the invention described herein is generally more applicable to SBS-based thermally processed plates which tend to be more susceptible to printing blotter patterns.

The photocurable printing blank generally contains one or more layers of an uncured photocurable material on a suitable backing layer. The photocurable printing blank can be in the form of a continuous (seamless) sleeve or a flat, planar plate that is mounted on a carrier sleeve. In addition, the plate can be held onto the carrier sleeve using any suitable means, including vacuum, adhesive, and/or mechanical clamps.

The printing element is selectively exposed to actinic radiation in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer that is sensitive to laser ablation. A laser is then used to ablate selected areas of the actinic radiation opaque layer creating an in situ negative. In the third alternative, a focused beam of actinic radiation is used to selectively expose the photopolymer. Any of these alternative methods is acceptable, with the criteria being the ability to selectively expose the photopolymer to actinic radiation thereby selectively curing portions of the photopolymer.

In one embodiment, the printing element comprises a photopolymer layer that is coated with an actinic radiation (substantially) opaque layer, which typically comprises carbon black, and which is sensitive to laser ablation. A laser, which is preferably an infrared laser, is then used to ablate selected areas of the actinic radiation opaque layer creating an in situ negative. This technique is well-known in the art, and is described for example in U.S. Pat. Nos. 5,262,275 and 6,238,837 to Fan, and in U.S. Pat. No. 5,925,500 to Yang et al., the subject matter of each of which is herein incorporated by reference in its entirety.

The selected areas of the photopolymer layer revealed during laser ablation are then exposed to actinic radiation to crosslink and cure the portions of the photopolymer layer that are not covered by the in situ negative. The type of radiation used is dependent on the type of photoinitiator in the photopolymerizable layer. The radiation-opaque material in the infrared sensitive layer which remains on top of the photopolymerizable layer prevents the material beneath from being exposed to the radiation and thus those areas covered by the radiation-opaque material do not polymerize. The areas not covered by the radiation-opaque material are exposed to actinic radiation and polymerize and thus crosslink and cure. Any conventional sources of actinic radiation can be used for this exposure step. Examples of suitable visible or UV sources include carbon arcs, mercury-vapor arcs, fluorescent lamps, electron flash units, electron beam units and photographic flood lamps.

Next, the photopolymer layer of the printing element is thermally processed or developed to remove uncured (i.e., non-crosslinked) portions of the photopolymer, without disturbing the cured portions of the photopolymer layer, to produce the relief image.

The thermal processing step typically comprises heating the at least one layer of photocurable material to soften uncured portions of the at least one photocurable layer and causing contact between the at least one photocurable layer and a blotting material, wherein the blotting material removes the softened uncured portions of the at least one photocurable layer. The blotting material preferably comprises paper or woven or non-woven fabrics. Typical blotting materials include screen mesh and absorbent fabrics, including polymer-based and non-polymer-based fabrics.

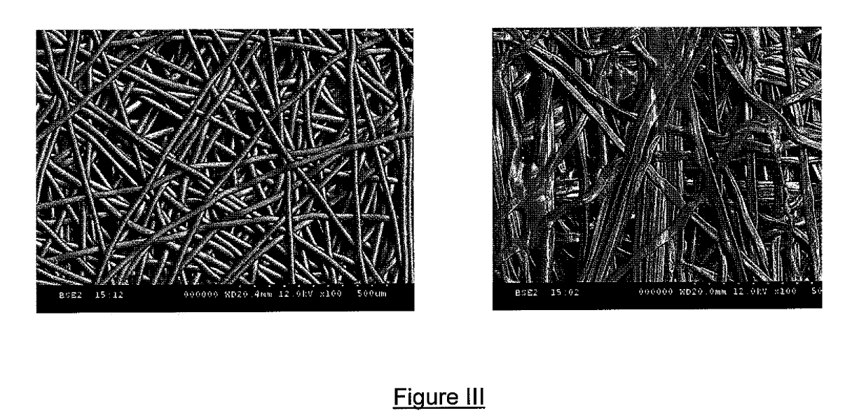

Blotter materials were shown to have an effect on relief. For example, Cerex® 23, a spunbonded nylon 6,6 non-woven blotting materials (available from Cerex America, Inc.) and Ahlstrom® 100% cotton blotting papers (available from Ahlstrom, Inc.) were investigated. SEM pictures of both of these blotter materials are provided in FIG. 3. As can be seen in FIG. 3, which depicts the SEM pictures of both blotting materials, Cerex® is composed of numerous round fibers that are highly entangled in one another. On the other hand, the Ahlstrom® blotting material consists of rather flat fibers. This difference in morphology between the two blotting materials explains why the Ahlstrom® materials gives lower surface roughness than the Cerex® material—the flat fibers of the Ahlstrom® material leave much less fabric patterns on the surface of the photoresin, thus giving rise to lower surface roughness. However, due to the flat nature of the fibers in the Ahlstrom® materials, the surface areas of the fibers put in contact with the photoresin material during the thermal processing step is typically much less than with the Cerex® material, which also gives smaller relief. Thus, it can be seen that there are pros and cons for the use of both types of blotter materials in the thermal processing step.

In addition, generally Cerex® 23, a spunbonded nylon 6,6 non-woven material (available from Cerex America, Inc) and other similar blotting materials are more efficient in removing uncured photoresin than Ahlstrom® and other similar blotting materials while Ahlstrom® gives lower surface roughness than Cerex®. It was further found that output of IR power and squeeze type did not influence surface roughness under typical processing conditions for hot roll temperature and front exposure time.

After thermal processing, the printing elements may be further processed. For example, the plates may be finished using a five-minute post exposure and a six-minute, 30 second detack time. Other post-exposure and detack processes and conditions are also usable in the practice of the invention.

Table 2 depicts the surface roughness of a plate with respect to various process conditions.

TABLE 2
Surface Roughness of Plate with respect to Processing Condition

| | Hot Roll | | |
|---|---|---|---|
| | Temperature | Front Exposure Time | Surface Roughness |
| Condition | (° C.) | (Minutes) | (nm) |
| 1 | 140 | 10 | 720.07 |
| 2 | 140 | 30 | 593.42 |
| 3 | 180 | 10 | 569.05 |
| 4 | 180 | 30 | 436.65 |

In general, it was found that as hot roll temperature increases, relief becomes larger while forward exposure time has no effect.

Surface roughness measurements were performed in the following manner:

Each processed plate was cut in half to produce two plates of approximately the same size. Next, an optical profiler (Veeco® NT3300 optical profiler) was set on VSI mode with a 20 μm back measure and a 20 μm front measure at a speed of 3×. at this point, each half was measured using the same settings in twenty-two different previously labeled spots, for a total of forty-four measurements per plate.

Next, a relief measure was taken by using the first template made as a template to mark sixteen measurement points dispersed throughout the plate. Each measurement was made using a Sivac® probe with D80S display. High and low readings were double checked where appropriate to ensure that the measurements were valid.

What is claimed is:

1. A method of producing a flexographic printing element, the method comprising the steps of:
a) providing a printing element blank, said printing element blank comprising:
i) a support layer;
ii) at least one photocurable layer on the support layer, the at least one photocurable layer comprising:
1) a binder comprising styrene-butadiene-styrene;
2) at least one fast curing monomer;
3) at least one slow curing monomer; and
4) a photoinitiator;
iii) optionally, an actinic radiation opaque laser ablatable layer on top of the at least one photocurable layer, said laser ablatable layer being capable of being ablated by exposure to infrared laser radiation; and
iv) optionally, a removable coversheet;
b) selectively imagewise exposing the printing plate blank to actinic radiation to selectively crosslink and cure portions of the at least one photocurable layer; and
c) thermally processing the at least one photocurable layer to remove uncured portions of the at least one photocurable layer, thereby revealing the relief image in the at least one photocurable layer;
wherein surface roughness of the relief image printing element after thermal processing is less than about 1,000 nm.

2. The method according to claim 1, wherein the surface roughness of the relief image printing plate after thermal processing is less than about 500 nm.

3. The method according to claim 1, wherein the thermal processing step comprises heating the at least one layer of photocurable material to soften uncured portions of the at least one photocurable layer and causing contact between the at least one photocurable layer and a blotting material, wherein the blotting material removes the softened uncured portions of the at least one photocurable layer.

4. The method according to claim 1, wherein the fast curing monomer is selected from the group consisting of hexanediol diacrylate, trimethylolpropane triacrylate, butanediol diacrylate, butylene glycol diacrylate, ethylene glycol diacrylate, pentanediol diacrylate, diethylene glycol diacrylate, propanediol diacrylate, tripropylene glycol diacrylate, diethylene glycol diacrylate, glycerol triacrylate, pentaerylthritol triacrylate, trimethylpropane triacrylate, propyloxyethylated trimethylolpropane triacrylate, petaerythritol tetraacrylate and combinations of the foregoing.

5. The method according to claim 3, wherein the fast curing monomer is present in the photocurable composition at a concentration of at least about 5% by weight, based on the total weight of the photocurable composition.

6. The method according to claim 1, wherein the slow curing monomer is selected from the group consisting of hexanediol dimethacrylate, trimethylolpropane trimethacrylate, ethylene glycol dimethacrylate, butylene glycol dimethacrylate, propanediol dimethacrylate, butylenes glycol dimethacrylate, propanediol dimethacrylate, pentanediol dimethacrylate, pentaerythritol trimethacrylate, butanetriol trimethacrylate, pentaerythritol tetamethacrylate, and trimethylol propane trimethacrcylate, and combinations of the foregoing.

7. The method according to claim 6, wherein the slow curing monomer is present in the photocurable composition at a concentration of about 1 to about 10% by weight, based on the total weight of the photocurable composition.

8. The method according to claim 1, wherein the thermal processing step takes place at a temperature of between about 140 and about 180° C.

9. The method according to claim 1, wherein the imagewise exposure step is performed for between about 5 and about 15 minutes.

10. The method according to claim 9, wherein the imagewise exposure step is performed for between about 8 and about 10 minutes.

11. A thermally processed relief image printing element, wherein the relief image printing element comprises at least one layer of photocurable material that crosslinks and cures upon exposure to actinic radiation, the at least one layer of photocurable material comprising (a) a binder comprising a styrene-butadiene-styrene block copolymer, (b) a fast curing monomer, and (c) a slow monomer; wherein after thermal processing, the relief image printing element has a surface roughness of less than about 1,000 mm

12. The thermally processed relief image printing element according to claim 11, wherein after thermal processing, the relief image printing element has a surface roughness of less than about 500 nm.

13. The thermally processed relief image printing element according to claim 11, wherein the slow curing monomer is selected from the group consisting of hexanediol dimethacrylate, trimethylolpropane trimethacrylate, ethylene glycol dimethacrylate, butylene glycol dimethacrylate, propanediol dimethacrylate, butylenes glycol dimethacrylate, propanediol dimethacrylate, pentanediol dimethacrylate, pentaerythritol trimetharcylate, butanetriol trimethacrylate, pentaerytlritol tetramethacrylate, and trimethylol propane trimethacrylate and combinations of the foregoing.

14. The thermally processed relief image printing element according to claim 11, wherein the fast curing monomer is selected from the group consisting of hexanediol diacrylate, trimethylolpropane triacrylate, butanediol diacrylate, butylene glycol diacrylate, ethylene glycol diacrylate, pentanediol diacrylate, diethylene glycol diacrylate, propanediol diacrylate, tripropylene glycol diacrylate, diethylene glycol diacrylate, glycerol triacrylate, pentaerylthritol triacrylate, trimethylpropane triacrylate, propyloxyethylated trimethylolpropane triacrylate, petaerythritol tetraacrylate and combinations of the foregoing.
